(19) United States
(12) Patent Application Publication
(10) Pub. No.: US 2025/0287682 A1
(43) Pub. Date: Sep. 11, 2025

(54) SIC PLANAR MOSFETS WITH IMPROVED PERFORMANCE STRUCTURES

(71) Applicant: Nami MOS CO., LTD., New Taipei City (TW)

(72) Inventors: FU-YUAN HSIEH, New Taipei City (TW); LIN XU, SHANGHAI (CN)

(73) Assignees: Nami MOS CO., LTD., New Taipei City (TW); MOSEL VITELIC INC., Hsinchu (TW)

(21) Appl. No.: 18/595,806

(22) Filed: Mar. 5, 2024

(51) Int. Cl. H01L 29/78; H01L 29/06; H01L 29/10; H01L 29/16; H01L 29/423

(52) U.S. Cl. CPC H10D 84/146; H10D 62/107; H10D 62/393; H10D 62/8325; H10D 64/519

(57) ABSTRACT

An improved silicon carbide (SiC) planar MOSFET having at least one buried P-shield (BPS) region including one center portion and two side portions for the gate oxide electric field and saturation current reductions is disclosed. Two saturation current pitching (SCP) structures formed in two Junction Field Effect Transistor (JFET) regions sandwiched between the side portions and the center portion of the BPS region limit a saturation current of the device in a forward conduction stage for the short-circuit capability improvement. Moreover, a Junction barrier Schottky diode (JBSD) is integrated with the SiC MOSFET in a location between the two adjacent split gate electrodes for the reverse conduction switching loss reduction.

### FIELD OF THE INVENTION

This invention relates generally to semiconductor devices having multiple stepped buried P-shield (MSBPS) regions, and more particularly, to a silicon carbide (SiC) planar Metal Oxide Semiconductor Field Effect Transistor (MOSFET) having a first buried P-shield (BPS) region including one center portion and two side portions for the gate oxide electric field and saturation current reductions. Moreover, a Junction Barrier Schottky diode (JBSD) is integrated with the SiC MOSFET in a location between two adjacent split gate electrodes for the reverse conduction switching loss reduction.

### BACKGROUND OF THE INVENTION

Because of the physical properties of SiC, SiC-MOSFETs can achieve a higher breakdown voltage, a lower on-resistance and a higher switching speed than Si-MOSFETs. However, SiC-MOSFETs have a much higher electric-field strength at the gate oxide than Si-MOSFETs because the breakdown electric field strength of SiC is 10 times higher than that of Si. To resolve this problem, a P+ shielding region is disposed under an N+ source region as well as a P-base region as shown in FIG. 1 (FIG. 10.1 of Silicon Carbide Power Devices, B Jayant Baliga's book, page 260) as a field relaxing layer near the gate oxide. Unfortunately, a short-circuit (SC) failure is still the most serious reliable issue for the shielded SiC-MOSFETs device due to the much smaller device area comparing with Si-MOSFETs resulting in a higher junction temperature before the failure. During the SC transient process, the high direct current (DC) voltage and the large saturation current would be applied to the device, resulting in the device's performance degradation or even severe burnout failure if the devices do not have a sufficient SC withstand capability.

Therefore, there is still a need in the art of the SiC-MOSFETs design and fabrication to provide a novel cell structure, device configuration and manufacturing process that would make the SiC-MOSFETs have a lower electric-field strength at the gate oxide, achieve a lower specific on-resistance and have a lower saturation current for the short circuit capability improvement.

### SUMMARY OF THE INVENTION

The present invention discloses a SiC planar MOSFET having multiple stepped buried P-shield (MSBPS) regions of a second conductivity adjoining a body region with different doping concentrations increasing stepwise in a direction from the body region toward a substrate, and multiple stepped Field Effect Transistor (JFET) regions of a first conductivity type sandwiched between the adjacent MSBPS regions with different widths decreasing stepwise in a direction from the body region toward the substrate; multiple saturation current pinching (SCP) structures formed in the multiple stepped JFET (MSJ) regions between the adjacent MSBPS regions clamp the potential, thus limiting the saturation current in a forward conduction stage for the short-circuit capability improvement. The gate oxide electric field strength is also reduced by the existence of the MSBPS regions as a high electric field is shifted from a channel region to a central gate electrode region.

According to one aspect, the invention features a SiC device comprising a plurality of unit cells with each unit cell in an active area, comprising: an epitaxial layer grown on a substrate; a source region of a first conductivity type formed at a top portion of the epitaxial layer and encompassed in a body region of a second conductivity type; a planar gate electrode made of a doped poly-silicon layer padded by a gate oxide; a first type JFET (JFET1) region of the first conductivity type formed between the two adjacent body regions; MSBPS regions of the second conductivity type adjoining the body region with different doping concentrations increasing stepwise in a direction from the body region toward the substrate; The MSJ regions of the first conductivity type sandwiched between the two adjacent MSBPS regions with different widths decreasing stepwise in a direction from the body region toward the substrate; and an N-drift (ND) region of the first conductivity type formed between the substrate and the JFET1 region.

According to another aspect, in some preferred embodiments, the MSJ regions have different doping concentrations increasing stepwise in a direction from the JFET1 region toward the substrate.

According to another aspect, in some preferred embodiments, the JFET1 region has a width greater than the widths of the MSJ regions, and has a doping concentration less than doping concentrations of the MSJ regions.

According to another aspect, in some preferred embodiments, the MSBPS regions comprising at least two BPS regions and the MSJ regions comprising at least two JFET regions.

According to another aspect, the invention also features a SiC device comprising a plurality of unit cells with each unit cell in an active area, comprising: an epitaxial layer grown on a substrate; a source region of a first conductivity type formed at a top portion of the epitaxial layer and encompassed in a body region of a second conductivity type; a planar gate electrode made of a doped poly-silicon layer padded by a gate oxide; a first type JFET (JFET1) region of the first conductivity type formed between the two adjacent body regions; a first BPS (BPS1) region of the second conductivity type formed below the body region and the JFET1 region having a left side portion BPS1L, a center portion BPS1C, a right side portion BPS1R and connection portions BPS1G; the BPS1G connecting the BPS1C together with the BPS1L and/or the BPS1R to a source metal through the body region; a second type JFET (JFET2) region having a left side portion JFET2L formed between the BPS1L and the BPS1C, and a right side portion JFET2R formed between the BPS1C and the BPS1R; and an ND region of the first conductivity type formed between the substrate and the JFET1 region.

According to another aspect, the invention features an improved SiC device having a single gate electrode padded with a gate oxide having a central thick gate oxide under a center of the single gate electrode.

According to another aspect, the invention features an improved SiC device with a planar gate electrode having two split gate electrodes in each unit cell, and further comprising a Junction Barrier Schottky diode (JBSD) embedded between the two adjacent gate electrodes by making a Schottky contact with the JFET1 region and the two P+ regions of a second conductivity type within the JFET1 region.

According to another aspect, the invention features an improved SiC device with a planar gate electrode having two split gate electrodes in each unit cell, and further comprising a P/N (P-type/N-type) junction diode embedded between the two adjacent split gate electrodes by making a p+ region of a second conductivity type within the JFET1 region of a first conductivity type, wherein the p+ region is spaced apart from the body region for the gate oxide electric field reduction.

According to another aspect, the present invention also features a SiC device further comprising a second BPS (BPS2) region of the second conductivity type formed below the BPS1 region and a third type JFET (JFET3) region formed between the two adjacent BPS2 regions; the BPS2 region having a doping concentration higher than that of the BPS1 region, and having a width greater than that of the BPS1 region.

According to another aspect, the present invention also features a SiC device further comprising a CSL below the BPS2 and the JFET3 regions with a doping concentration higher than that of the ND region.

According to another aspect, in some preferred embodiments, the JFET2 region has a doping concentration higher than that of the JFET1 region.

According to another aspect, the present invention also features a SiC device further comprising a super junction structure comprising a P column region of the second conductivity type disposed above the substrate.

According to another aspect, in some preferred embodiments, the substrate has the first conductivity type and further comprises a buffer layer of the first conductivity type with a resistivity Rb sandwiched between the substrate and the epitaxial layer with a resistivity R, wherein R<Rb.

According to another aspect, in some preferred embodiments, the substrate has the second conductivity type and further comprises a buffer layer of the first conductivity type with a resistivity Rb sandwiched between the substrate and the epitaxial layer with a resistivity R, wherein R>Rb.

According to another aspect, in some preferred embodiments, the substrate has the second conductivity type, further comprises a buffer layer of the first conductivity type formed sandwiched between the substrate and the epitaxial layer; a plurality of heavily doped regions of the first conductivity type in the substrate to form a plurality of alternating P+ and N+ regions in the substrate.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1 is a cross-sectional view of a SiC shielded MOSFET device of a prior art.

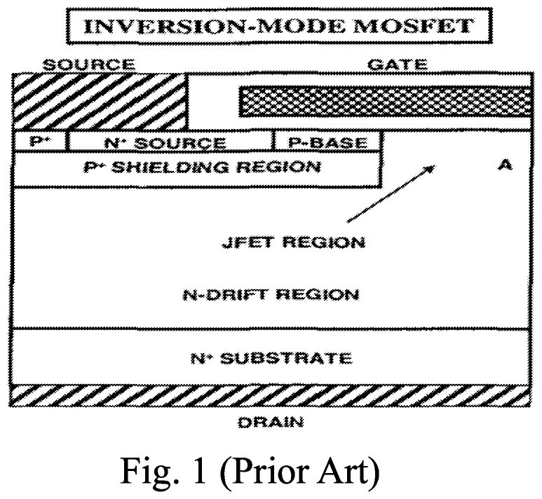

FIG. 2A is a cross-sectional view of a preferred embodiment wherein doping concentration variations of the P type regions (from p body region to BPS2 region) and the N type regions (from JFET1 region to N+ substrate) are depicted separately along the vertical direction according to the present invention.

FIG. 2B is a cross-sectional view of another preferred embodiment with a current spreading layer (CSL) wherein doping concentration variations of the P type regions (from p body region to BPS2 region) and the N type regions (from JFET1 region to N+ substrate) are depicted separately along the vertical direction according to the present invention.

FIG. 2C is a cross-sectional view of another preferred embodiment with three MSBPS regions wherein doping concentration variations of the P type regions (from p body region to BPS2 region) and the N type regions (from JFET1 region to N+ substrate) are depicted separately along the vertical direction according to the present invention.

FIG. 2D is a cross-sectional view of another preferred embodiment having a super junction structure in FIG. 2A according to the present invention.

FIG. 2E is a cross-sectional view of another preferred embodiment having a buffer layer in FIG. 2D according to the present invention.

FIG. 2F is a cross-sectional view of another preferred embodiment according to the present invention, which is same as FIG. 2E except that the substrate conductivity type is P type.

FIG. 2G is a cross-sectional view of another preferred embodiment according to the present invention, which is same as FIG. 2F except that the substrate has a plurality of alternating P+ and N+ regions.

FIG. 3A is a top view of a preferred embodiment according to the present invention.

FIG. 3B is a cross-sectional view of a SiC device showing a preferred embodiment along A1-A1′ line of FIG. 3A according to the present invention.

FIG. 3C is a cross-sectional view of a SiC device showing a preferred embodiment along B1-B1′ line of FIG. 3A according to the present invention.

FIG. 3D is a top view of another preferred embodiment according to the present invention.

FIG. 3E is a cross-sectional view of a SiC device showing a preferred embodiment along A2-A2′ line of FIG. 3D according to the present invention.

FIG. 3F is a cross-sectional view of a SiC device showing a preferred embodiment along B2-B2′ line of FIG. 3D according to the present invention.

FIG. 3G is a cross-sectional view of a SiC device showing another preferred embodiment along A2-A2′ line of FIG. 3D according to the present invention.

FIG. 3H is a cross-sectional view of a SiC device showing another preferred embodiment along A2-A2′ line of FIG. 3D according to the present invention.

FIG. 3I is a cross-sectional view of a SiC device showing another preferred embodiment along A2-A2′ line of FIG. 3D according to the present invention.

FIG. 3J is a cross-sectional view of a SiC device showing another preferred embodiment along A2-A2′ line of FIG. 3D according to the present invention.

FIG. 3K is a cross-sectional view of a SiC device showing another preferred embodiment along A2-A2′ line of FIG. 3D according to the present invention.

FIG. 4A is a cross-sectional view of another preferred embodiment according to the present invention.

FIG. 4B is a cross-sectional view of another preferred embodiment according to the present invention.

FIG. 4C is a cross-sectional view of another preferred embodiment according to the present invention.

FIG. 4D is a cross-sectional view of another preferred embodiment according to the present invention.

FIG. 4E is a cross-sectional view of another preferred embodiment according to the present invention.

FIG. 4F is a cross-sectional view of another preferred embodiment according to the present invention.

FIG. 4G is a cross-sectional view of another preferred embodiment according to the present invention.

FIG. 4H is a cross-sectional view of another preferred embodiment according to the present invention.

FIG. 5A is a cross-sectional view of another preferred embodiment integrated with an embedded JBSD wherein doping concentration variations of the P type regions (from p body region to BPS2 region) and the N type regions (from JFET1 region to N+ substrate) are depicted separately along the vertical direction according to the present invention.

FIG. 5B is a cross-sectional view of a SiC device showing another preferred embodiment along A2-A2′ line of FIG. 3D according to the present invention.

FIG. 5C is a cross-sectional view of a SiC device showing another preferred embodiment along A2-A2′ line of FIG. 3D according to the present invention.

FIG. 5D is a cross-sectional view of another preferred embodiment according to the present invention.

FIG. 6A is a cross-sectional view of another preferred embodiment wherein doping concentration variations of the P type regions (from p body region to BPS2 region) and the N type regions (from JFET1 region to N+ substrate) are depicted separately along the vertical direction according to the present invention.

FIG. 6B is a cross-sectional view of a SiC device showing another preferred embodiment along A2-A2′ line of FIG. 3D according to the present invention.

FIG. 6C is a cross-sectional view of a SiC device showing another preferred embodiment along A2-A2′ line of FIG. 3D according to the present invention.

FIG. 6D is a cross-sectional view of another preferred embodiment according to the present invention.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

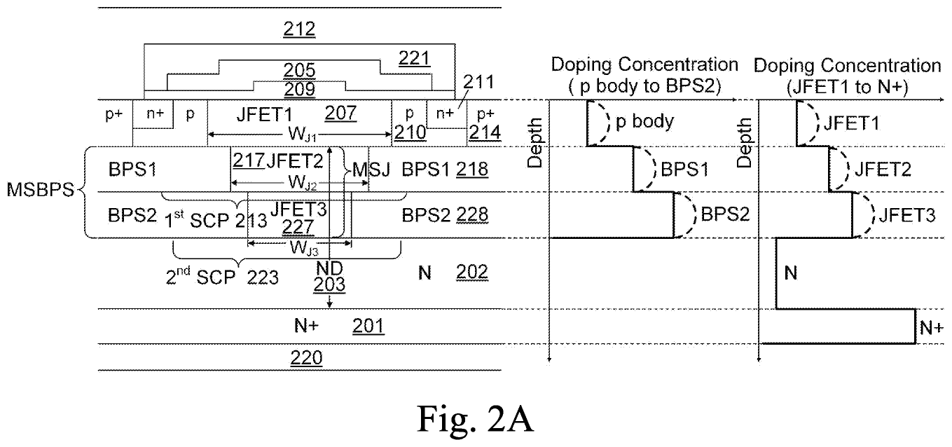

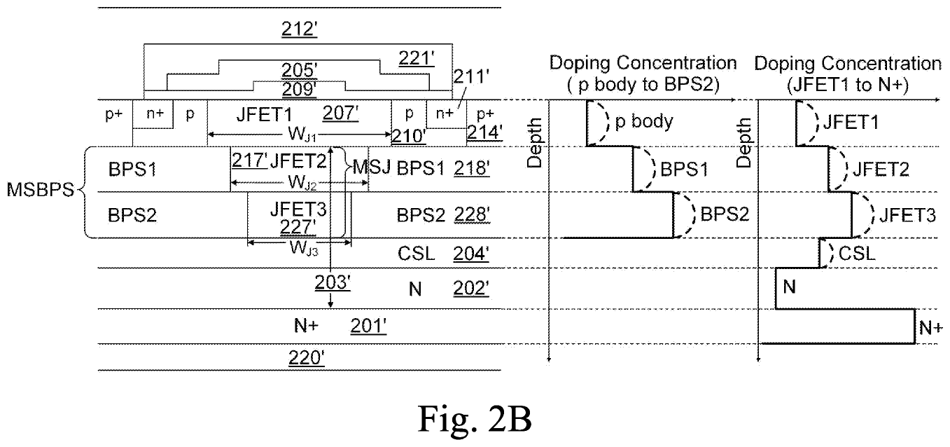

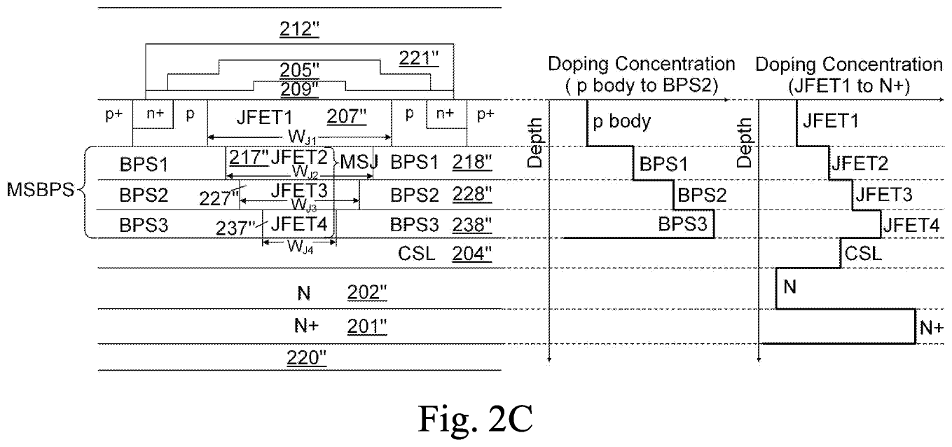

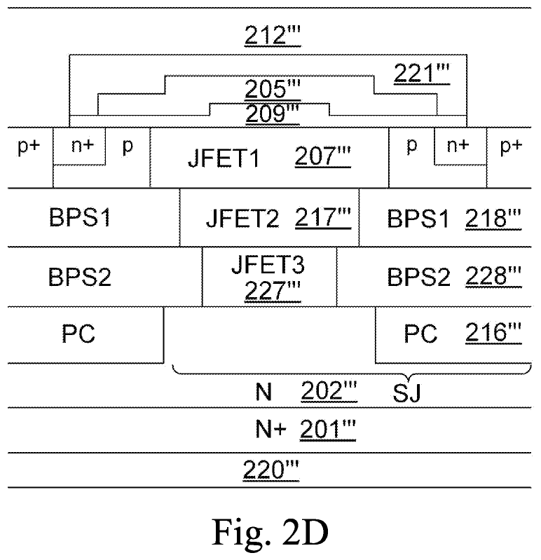

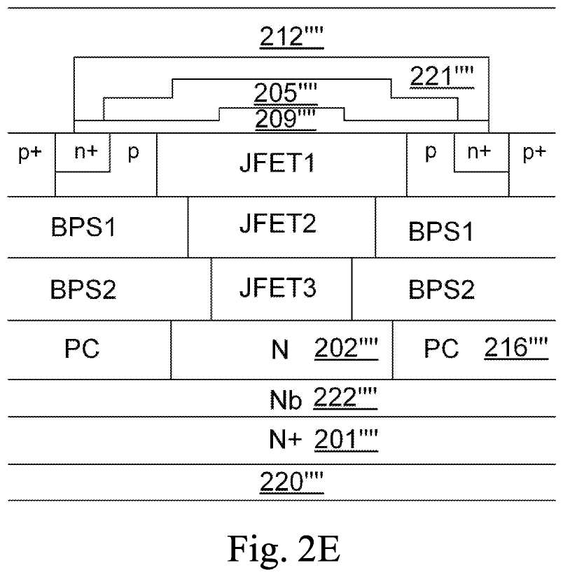

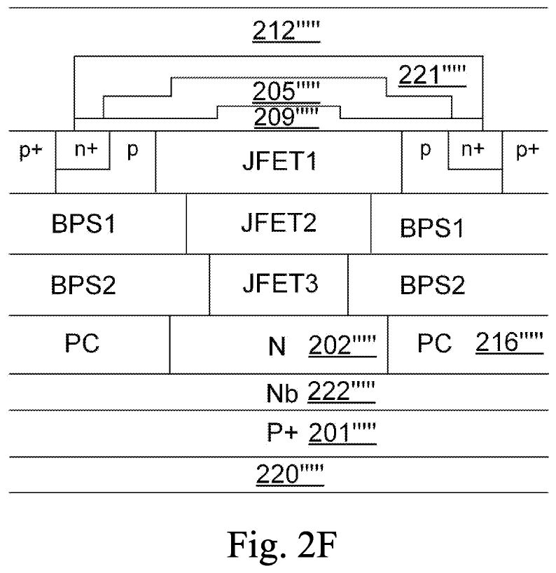

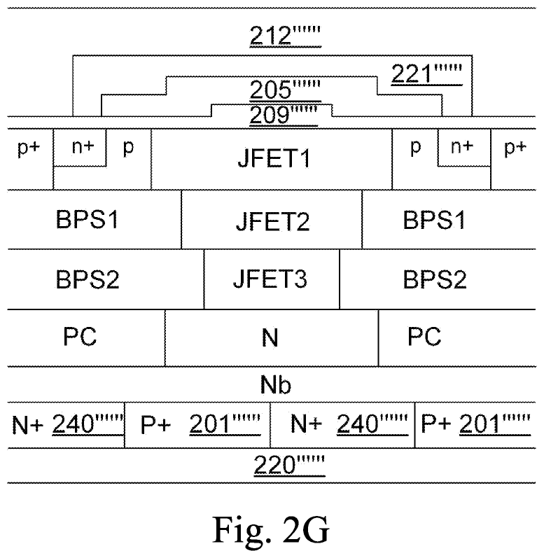

Please refer to FIG. 2A for a preferred embodiment of this invention with a new and improved device structure wherein doping concentration variations of the P type regions (from p body region to BPS2 region) and the N type regions (from JFET1 region to N+ substrate) are depicted separately along the vertical direction. The preferred embodiment comprises a SiC device formed on an N+ type SiC substrate 201 with a less doped N type SiC epitaxial layer 202 extending thereon, wherein the N+ substrate 201 is coated with a back metal 220 on the rear side as a drain metal. The p body regions 210 and n+ source regions 211 are formed at a top portion of the N type SiC epitaxial layer 202, wherein the n+ source regions 211 are encompassed in the p body regions 210 and a first type JFET (JFET1, as illustrated) region 207 is formed between the two adjacent p body regions 210 with a doping concentration D_{JFET1}, wherein D_{JFET1} is higher than a doping concentration D_{N} of the N type epitaxial layer 202, that is D_{JFET1}>D_{N}. An N-drift (ND, as illustrated) region 203 of the first conductivity type is formed between the N+ substrate 201 and the JFET1 region 207. Inside the N type epitaxial layer 202, multiple stepped buried P-shield (MSBPS, as illustrated) regions of the second conductivity type are formed adjoining the body region 210 including a bottom second BPS (BPS2, as illustrated) region 228 with a doping concentration D_{BPS2} and a top first BPS (BPS1, as illustrated) region 218 above the BPS2 region 228 with a doping concentration D_{BPS1}, wherein D_{BPS1}<D_{BPS2}. As a doping concentration Dₚ of the p body region 210 is lower than the D_{BPS1}, the relationship among the doping concentrations of the P type regions is Dₚ<D_{BPS1}<D_{BPS2}. A p+ heavily doped region 214 is formed in one side of the p body region 210 above the MSBPS regions opposite to the JFET1 region 207. Meanwhile, multiple stepped JFET (MSJ, as illustrated) regions of the first conductivity type are formed adjoining the JFET1 region 207 sandwiched between the two adjacent MSBPS regions, comprising a second type JFET (JFET2, as illustrated) region 217 with a width W_{J2} and a doping concentration D_{JFET2} and a third type JFET (JFET3, as illustrated) region 227 below the JFET2 region 227 with a width W_{J3} and a doping concentration D_{JFET3}, wherein W_{J2}>W_{J3} and D_{JFET2}<D_{JFET3}, while W_{J2} is less than a width W_{J1} of the JFET1 region 207 and D_{JFET2} is higher than a doping concentration D_{JFET1} of the JFET1 region 207, the relationships among widths and doping concentrations of the three type JFET regions are W_{J1}>W_{J2}>W_{J3} and D_{JFET1}<D_{JFET2}<D_{JFET3}. Moreover, a first saturation current pinching (1^{st} SCP, as illustrated) structure 213 comprising a JFET2 region 217 sandwiched between the two top BPS1 regions 218 and a second saturation current pinching (2^{nd} SCP, as illustrated) structure 223 comprising a JFET3 region 227 sandwiched between the two bottom BPS2 regions 228 are formed to clamp the voltage, thus limiting the saturation current in a forward conduction stage for the short-circuit capability improvement. The doping concentration profile of each region of the MSBPS and the MSJ regions can be uniform (as shown by the solid line in FIG. 2A) or non-uniform with a peak doping concentration (as shown by the dashed line in FIG. 2A) in each region depending on the formation method of using epitaxial growth method for the solid line or ion implantation method for the dashed line. The doping concentration of each region of the MSBPS regions and MSJ regions specified herein or thereafter is defined by its maximum value. A doped poly-silicon layer padded by a gate oxide 209 is formed on the N type epitaxial layer 202 as a plan gate electrode 205 covering the top surfaces of the p body regions 210, the n+ source regions 211 and the JFET1 regions 207, wherein the gate oxide 209 has a thick oxide in its central portion. An interlayer dielectric film 221 is then stacked on the planar gate electrode 205, and a source metal 212 is formed onto the interlayer dielectric film 221, the n+ source regions 211 and the p regions 210. The MSBPS regions, the n+ source regions 211 and the p body regions 210 are further shorted together to the source metal 212.

Please refer to FIG. 2B for another preferred embodiment of this invention with a new and improved device structure wherein doping concentration variations of the P type regions (from p body region to BPS2 region) and the N type regions (from JFET1 region to N+ substrate) are depicted separately along the vertical direction. The SiC device has a similar structure to FIG. 2A, except that the present invention further comprises a current spreading layer (CSL, as illustrated) 204′ of the first conductivity type below the MSBPS and MSJ regions with a doping concentration higher than that of the N type epitaxial layer 202′ for the on-resistance reduction.

Please refer to FIG. 2C for another preferred embodiment of this invention with a new and improved device structure wherein doping concentration variations of the P type regions (from p body region to BPS2 region) and the N type regions (from JFET1 region to N+ substrate) are depicted separately along the vertical direction. The SiC device has a similar structure to FIG. 2B, except that the MSBPS regions in the present invention comprises a bottom third BPS (BPS3, as illustrated) region 238″ with a doping concentration D_{BPS3}, a middle second BPS (BPS2, as illustrated) region 228″ with a doping concentration D_{BPS2} and a top first BPS (BPS1, as illustrated) region 218″ above the middle BPS2 region 228″ with a doping concentration D_{BPS1}, wherein D_{BPS1}<D_{BPS2}<D_{BPS3}. Moreover, MSJ regions in the present invention comprises a second type JFET (JFET2, as illustrated) region 217″ with a width W_{J2} and a doping concentration D_{JFET2}, a third type JFET (JFET3, as illustrated) region 227″ below the JFET2 region 217″ with a width W_{J3} and a doping concentration D_{JFET3} and a fourth type JFET (JFET4, as illustrated) region 237″ below the JFET3 region 227″ with a width W_{J4} and a doping concentration D_{JFET4}, wherein W_{J2}>W_{J3}>W_{J4} and D_{JFET2}<D_{JFET3}<D_{JFET4}.

Please refer to FIG. 2D for another preferred embodiment of this invention with a new and improved device structure. The SiC device has a similar structure to FIG. 2A, except that the present invention further comprises P column (PC, as illustrated) regions 216′″of the second conductivity type formed adjoining bottom surfaces of the BPS2 regions 228′″ above the N+ substrate 201′″. A super junction (SJ, as illustrated) structure is thus generated by the N type epitaxial layer 202′″ and the PC region 216′″.

Please refer to FIG. 2E for another preferred embodiment of this invention with a new and improved device structure. The SiC device has a similar structure to FIG. 2D, except that the present invention further comprises an additional N buffer layer (Nb, as illustrated) 222″″ with a resistivity Rb sandwiched between the N+ substrate 201″″ and the PC regions 216″″, wherein Rb is higher than a resistivity R of the N type epitaxial layer 202″″.

Please refer to FIG. 2F for another preferred embodiment of this invention with a new and improved device structure. The SiC device has a similar structure to FIG. 2D, except for the different substrate. In this invention, the SiC device is formed on a P+ substrate 201″″′, and the invention in FIG. 2F further comprises an N buffer layer (Nb, as illustrated) 222″″′ with a resistivity Rb sandwiched between the P+ substrate 201″″′ and the PC regions 216″″′, wherein Rb is lower than a resistivity R of the N type epitaxial layer 202″″′.

Please refer to FIG. 2G for another preferred embodiment of this invention with a new and improved device structure. The SiC device has a similar structure to FIG. 2F, except that, the SiC device in FIG. 2G further comprises a plurality of heavily doped N+ regions 240″″″ in the P+ substrate 201″″″ to form a plurality of alternating P+ and N+ regions in the substrate.

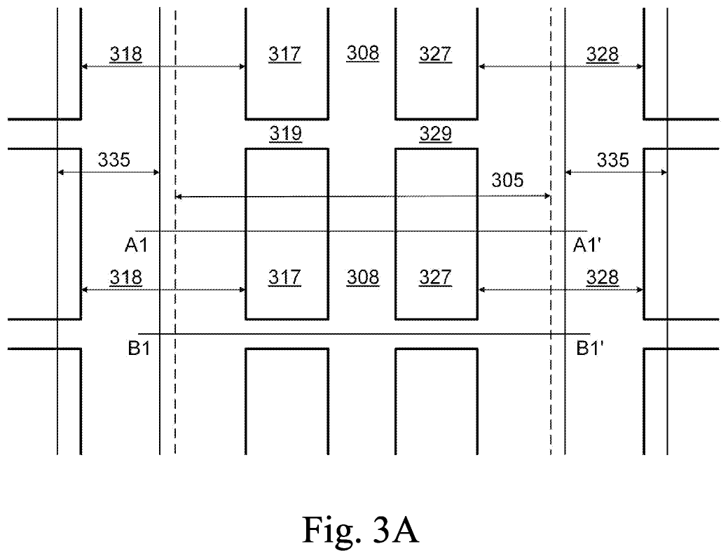

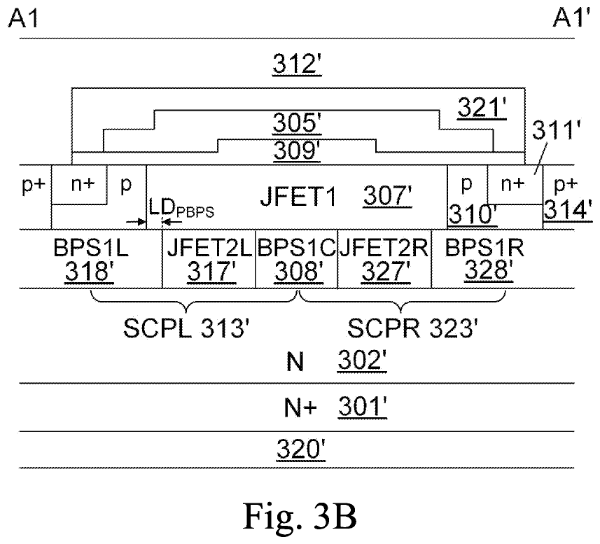

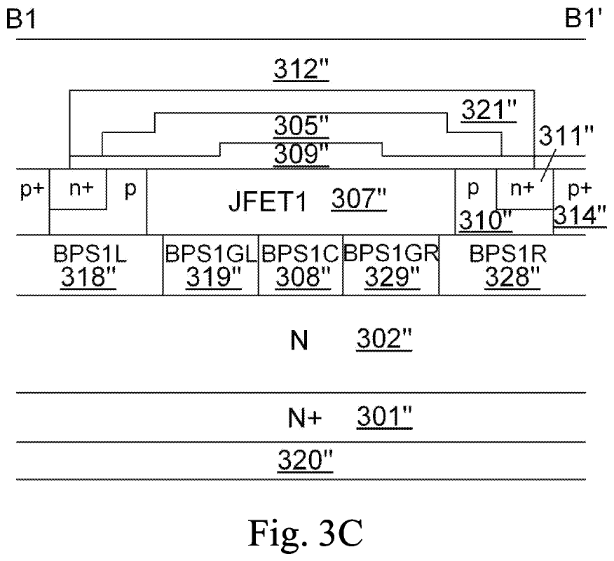

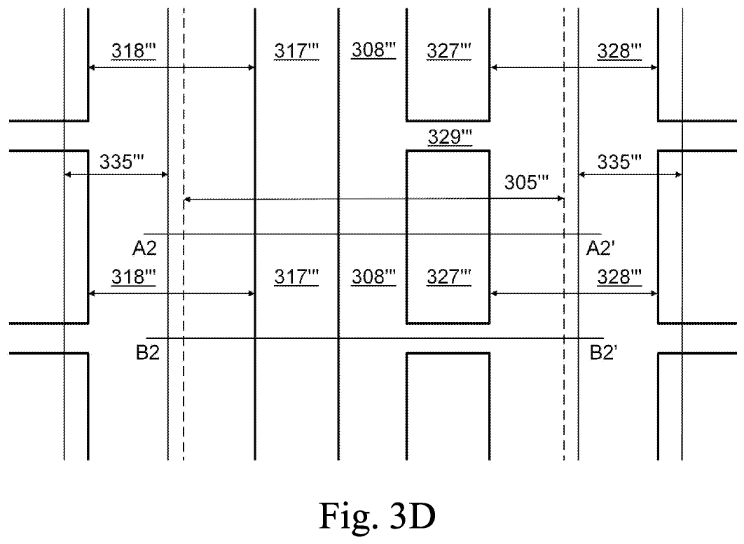

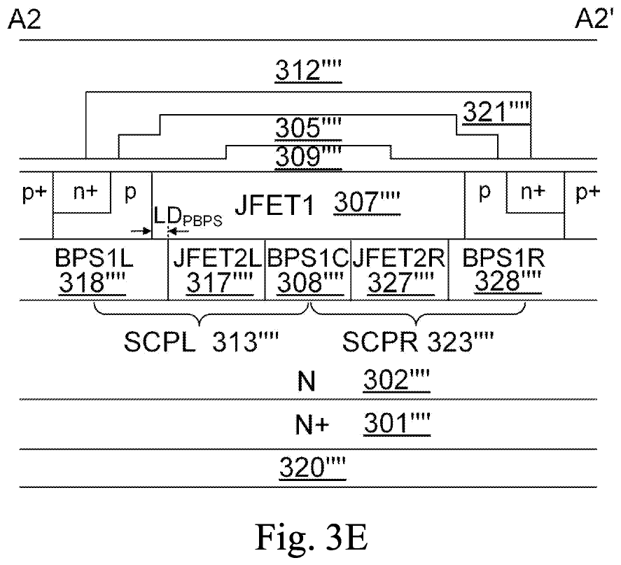

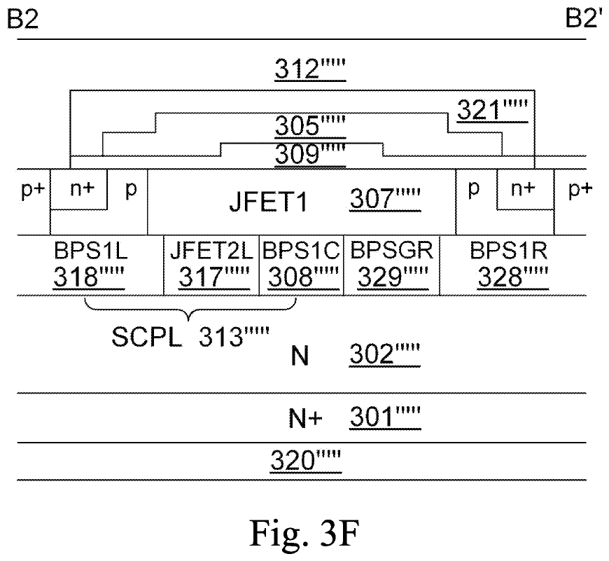

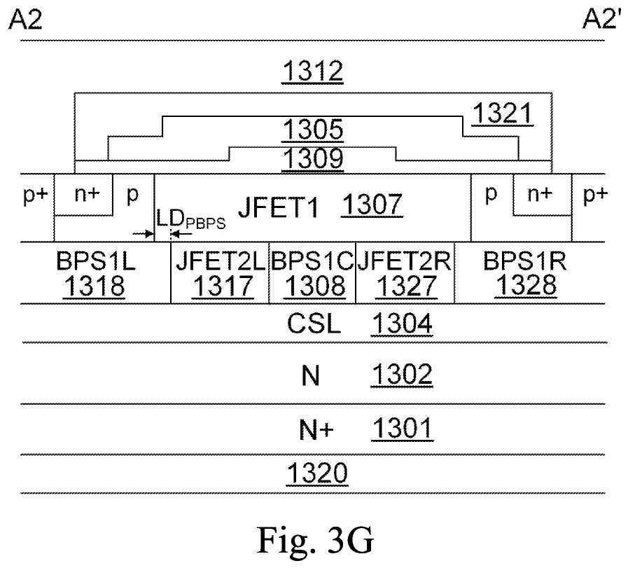

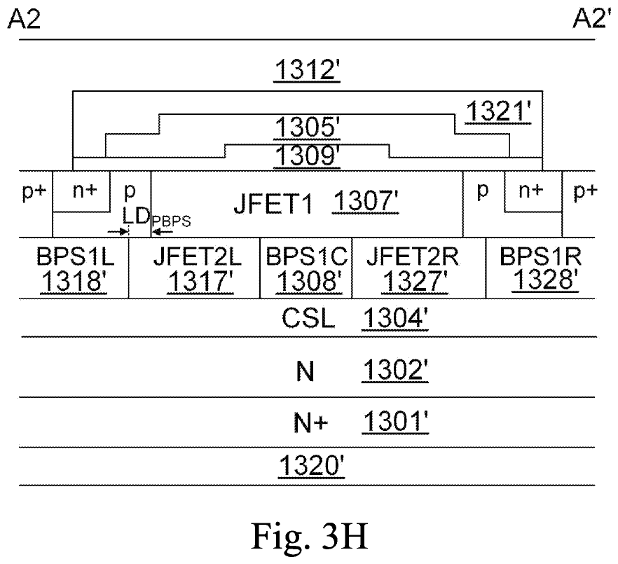

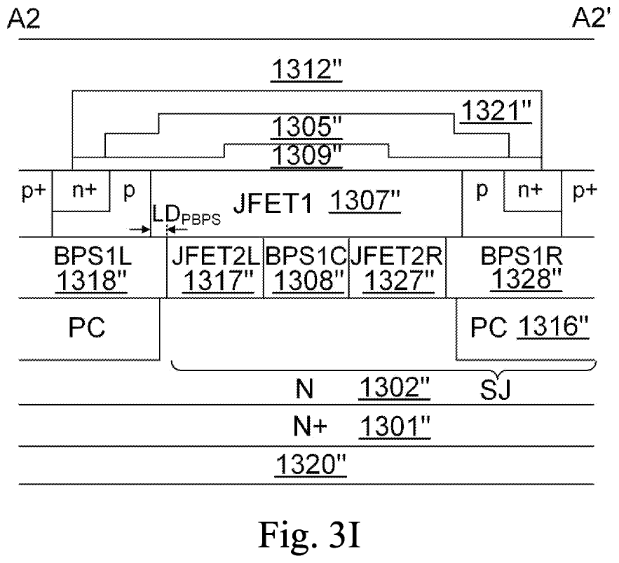

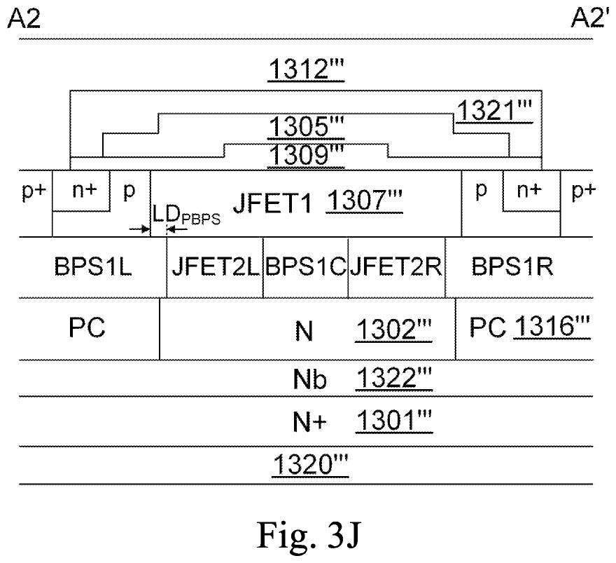

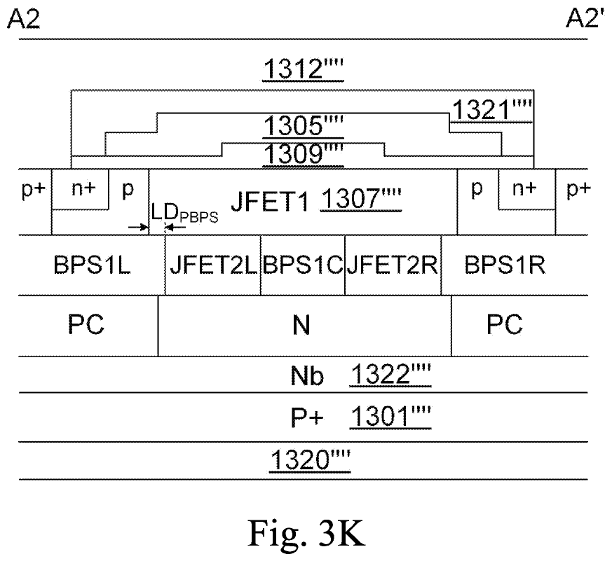

Please refer to FIG. 3A for a top view of a preferred embodiment for a SiC device comprising a plurality of unit cells with each unit cell in an active area. A first BPS region of the second conductivity type is formed including a left side portion BPS1L 318, a central portion BPS1C 308, a right side portion BPS1R 328 and connection portions BPS1G, wherein BPS1G comprises a left side portion BPS1GL 319 and a right side portion BPS1GR 329 and connect the BPS1C 308 together with BPS1L 318 and BPS1R 328 to a source metal through source contact 335 surrounded by a gate poly silicon layer 305 as a gate electrode. A second type JFET (JFET2) region is formed having a left side portion JFET2L 317 disposed between the BPS1L 318 and the BPS1C 308, and a right side portion JFET2R 327 disposed between the BPS1C 308 and the BPS1R 328.

Please refer to FIG. 3B for a cross-sectional view showing a preferred A1-A1′ cross section of FIG. 3A according to the present invention. The preferred embodiment comprises a SiC device formed on an N+ type SiC substrate 301′ with a less doped N type SiC epitaxial layer 302′ extending thereon, wherein the N+ substrate 301′ is coated with a back metal 320′ on the rear side as a drain metal. The p body regions 310′ and n+ source regions 311′ are formed at a top portion of the N type SiC epitaxial layer 302′, wherein the n+ source regions 311′ are encompassed in the p body regions 310′ and a first type JFET (JFET1, as illustrated) region 307′ is formed between the two adjacent p body regions 310′. Inside the N type epitaxial layer 302′, a first BPS region of the second conductivity type is formed including a left side portion BPS1L 318′, a center portion BPS1C 308′ and a right side portion BPS1R 328′, and the BPS1L 318′ is shifted from the p body region 310′ toward the center of the gate electrode 305′ by a distance LD_{PBPS}, wherein LD_{PBPS}>0. A second type JFET (JFET2) region is formed having a left side portion JFET2L 317′ and a right side portion JFET2R 327′. Therefore, a p+ heavily doped region 314′ is formed in one side of the p body region 310′ above the BPS1L region 318′ and BPS1R region 328′ opposite to the JFET1 region 307′. A dual saturation current pinching (SCP) structure is formed comprising a left side SCP (SCPL, as illustrated) structure 313′ and a right side SCP (SCPR, as illustrated) structure 323′ to clamp the voltage, wherein the SCPL structure comprises a JFET2L region 317′ sandwiched between the BPS1L region 318′ and the BPS1C region 308′, and the SCPR structure 323′ comprises a JFET2R region 327′ sandwiched between the BPS1C region 308′ and the BPS1R region 328′. A doped poly-silicon layer padded by a gate oxide 309′ is formed on the N type epitaxial layer 302′ as a planar gate electrode 305′ covering the top surfaces of the p body regions 310′, the n+ source regions 311′ and the JFET1 region 307′, wherein the gate oxide 309′ has a thick oxide in its central portion. An interlayer dielectric film 321′ is then stacked on the planar gate electrode 305′, and a source metal 312′ is formed onto the interlayer dielectric film 321′, the n+ source regions 311′ and the p body regions 310′. The BPS1L 318′, the BPS1R 328′, the n+ source regions 311′ and the p body regions 310′ are further shorted together to the source metal 312′.

Please refer to FIG. 3C for a cross-sectional view showing a preferred B1-B1′ cross section of FIG. 3A according to the present invention. The SiC device has a similar structure to FIG. 3B, except that the first BPS region in this invention comprises a left side portion BPS1L 318″, a center portion BPS1C 308″, a right side portion BPS1R 328″ and connection portions BPS1G, wherein BPS1G comprises BPS1GL 319″ and BPS1GR 329″ and connects the BPS1C 308″ together with the BPS1L 318″ and the BPS1R 328″ to a source metal 312″ through p body regions 310″. Moreover, the JFET2 region in FIG. 3B doesn't exist in this cross section.

Please refer to FIG. 3D for a top view of a preferred embodiment for a SiC device comprising a plurality of unit cells with each unit cell in an active area. The SiC device has a similar structure to FIG. 3A, except that the first BPS region of the second conductivity type in the present invention comprises a left side portion BPS1L 318′″, a center portion BPS1C 308′″, a right side portion BPS1R 328′″ and a right side connection portion BPSGR 329′″.

Please refer to FIG. 3E for a cross-sectional view showing a preferred A2-A2′ cross section of FIG. 3D according to the present invention, and the SiC device has a same structure as FIG. 3B.

Please refer to FIG. 3F for a cross-sectional view showing a preferred B2-B2′ cross section of FIG. 3D according to the present invention. The SiC device has a similar structure to FIG. 3C, except that the first BPS region in this invention comprises a left side portion BPS1L 318′″″, a center portion BPS1C 308′″″, a right side portion BPS1R 328′″″ and connection portion BPSGR 329′″″, and BPSGR 329″ connects the BPS1C 308′″″ together with BPS1R 328′″″ to a source metal 312′″″. Moreover, the present invention further comprises a second type JFET (JFET2) region having a left side portion JFET2L 317′″″ disposed between the BPS1L 318′″″ and the BPS1C 308′″″, and a single SCPL structure 313′″″ comprising a JFET2L 317′″″ is formed in this invention.

Please refer to FIG. 3G for a cross-sectional view showing another preferred A2-A2′ cross section of FIG. 3D according to the present invention. The SiC device has a similar structure to FIG. 3E, except that the present invention further comprises a current spreading layer (CSL, as illustrated) 1304 of the first conductivity type below the first BPS region and the second type JFET region with a doping concentration higher than that of the N type epitaxial layer 1302, wherein the first BPS region comprises a left side portion BPS1L 1318, a center portion BPS1C 1308 and a right side portion BPS1R 1328, and the second type JFET region comprises a left side portion JFET2L 1317 and a right side portion JFET2R 1327.

Please refer to FIG. 3H for a cross-sectional view showing another preferred A2-A2′ cross section of FIG. 3D according to the present invention. The SiC device has a similar structure to FIG. 3G, except that in the present invention, the LD_{PBPS}<0.

Please refer to FIG. 3I for a cross-sectional view showing another preferred A2-A2′ cross section of FIG. 3D according to the present invention. The SiC device has a similar structure to FIG. 3E, except that the present invention further comprises P column (PC, as illustrated) regions 1316″of the second conductivity type formed adjoining bottom surfaces the BPS1L region 1318″ and the BPS1R region 1328″ above the N+ substrate 1301″. A super junction (SJ, as illustrated) structure is thus generated by the N type epitaxial layer 1302″ and the PC region 1316″.

Please refer to FIG. 3J for a cross-sectional view showing another preferred A2-A2′ cross section of FIG. 3D according to the present invention. The SiC device has a similar structure to FIG. 31, except that the present invention further comprises an additional N buffer layer (Nb, as illustrated) 1322′″ with a resistivity Rb sandwiched between the N+ substrate 1301′″ and the PC regions 1316′″, wherein Rb is higher than a resistivity R of the N type epitaxial layer 1302′″.

Please refer to FIG. 3K for a cross-sectional view showing another preferred A2-A2′ cross section of FIG. 3D according to the present invention. The SiC device has a similar structure to FIG. 3I, except for the different substrate. In this invention, the SiC device is formed on a P+ substrate 1301″″, and the invention in FIG. 3K further comprises an N buffer layer (Nb, as illustrated) 1322″″ with a resistivity Rb sandwiched between the P+substrate 1301″″ and the PC regions 1316″″, wherein Rb is lower than a resistivity R of the N type epitaxial layer 1302″41 .

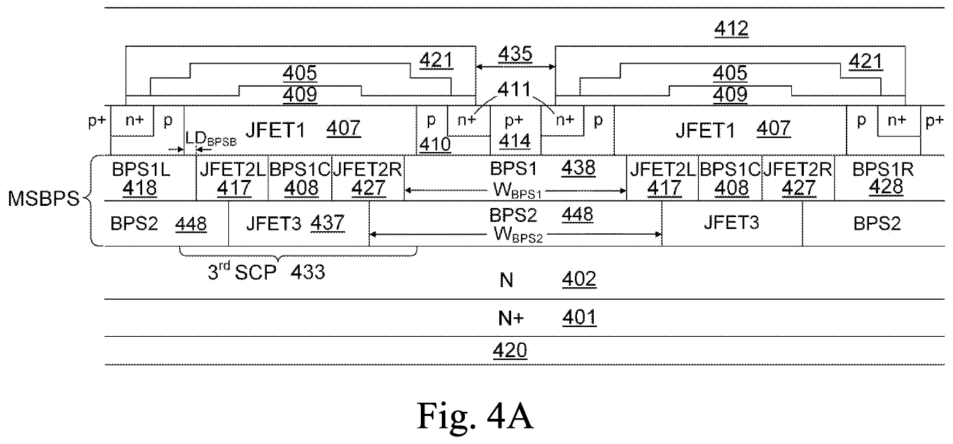

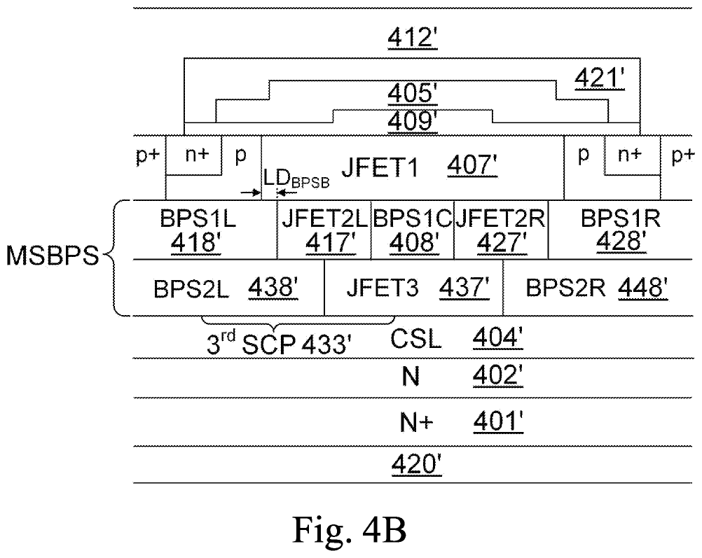

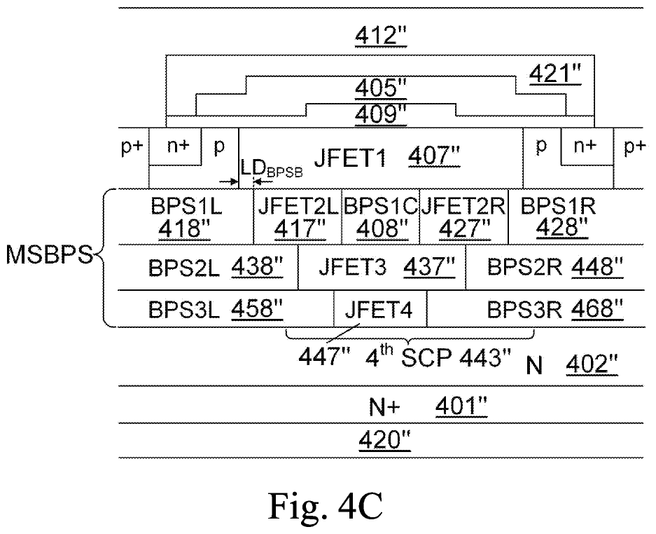

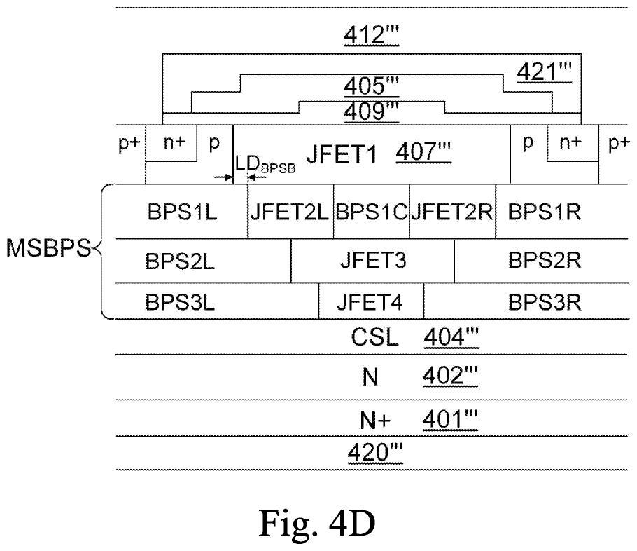

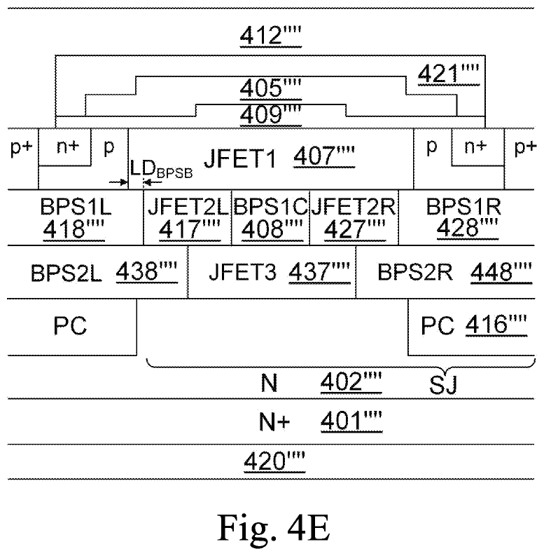

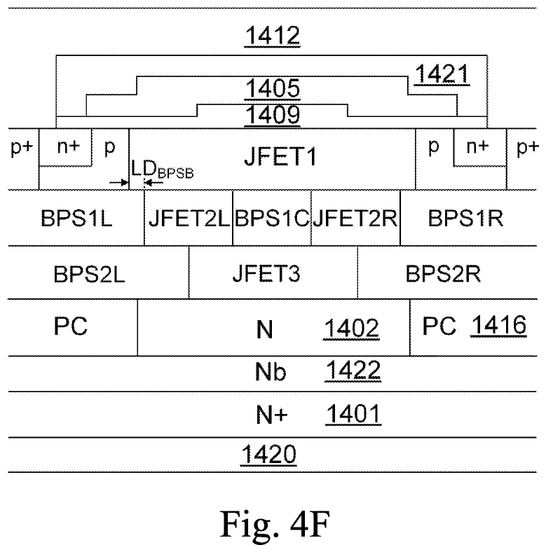

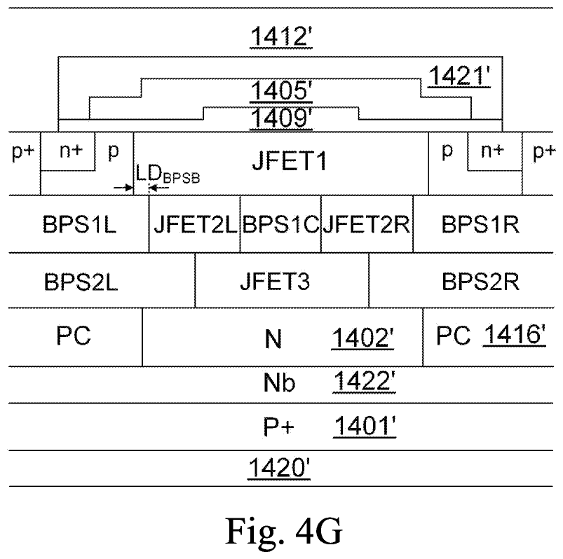

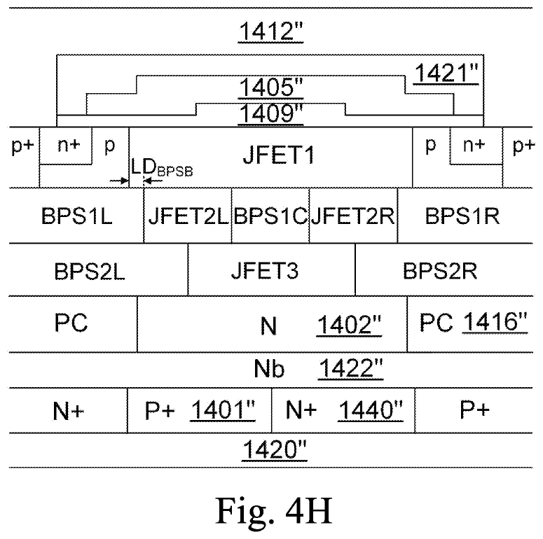

Please refer to FIG. 4A for another preferred embodiment of this invention with a new and improved device structure. The SiC device has a similar structure to FIG. 3B, except that the present invention in FIG. 4A has a cross sectional width twice of that in FIG. 3B, and further comprises a second BPS (BPS2, as illustrated) region 448 of the second conductivity formed below BPS1L region 418, BPS1R region 428 and BPS1 region 438, and a third type JFET (JFET3, as illustrated) region 437 formed between the two adjacent BPS2 regions 448, wherein the BPS2 region 448 has a doping concentration higher than that of the first type BPS region, and having a width W_{BPS2} greater than a width W_{BPS1} of the BPS1 region 438. The BPS1 regions 438, the BPS2 region 448, the n+ source regions 411 and the p body regions 410 are further shorted together to the source metal 412 through a source contact 435. Moreover, a third saturation current pinching (3^{rd} SCP, as illustrated) structure 433 comprising a JFET3 region 437 sandwiched between the BPS2 regions 448 is formed to further clamp the voltage.

Please refer to FIG. 4B for another preferred embodiment of this invention with a new and improved device structure. The SiC device has a similar structure to FIG. 3B, except that the present invention in FIG. 4B further comprises a second BPS region 448′ of the second conductivity including a left portion BPS2L 438′ and a right portion BPS2R 448′ formed below the BPS1L 418′ and the BPS1R 428′, respectively, wherein the BPS2 region has a doping concentration higher than that of the first type BPS region. Moreover, a third saturation current pinching (3^{rd} SCP, as illustrated) structure 433′ comprising a JFET3 region 437′ sandwiched between the BPS2L 438′ and the BPS2R 448′ is formed to further clamp the voltage. The present invention further comprises a current spreading layer (CSL, as illustrated) 404′ of the first conductivity type below the MSBPS regions with a doping concentration higher than a doping concentration of the N type epitaxial layer 402′.

Please refer to FIG. 4C for another preferred embodiment of this invention with a new and improved device structure. The SiC device has a similar structure to FIG. 4B, except that the present invention in FIG. 4C further comprises a third BPS region of the second conductivity including a left portion BPS3L 458″ and a right portion BPS3R 468″ formed below the BPS2L 438″ and BPS2R 448′, respectively. Moreover, a fourth saturation current pinching (4^{th} SCP, as illustrated) structure 443″ comprising a fourth type JFET (JFET4, as illustrated) region 447″ sandwiched between the BPS3L 458″ and the BPS3R 468″ is formed to further clamp the voltage, and the current spreading layer (CSL, as illustrated) 404′ in FIG. 4B doesn't exist in the present invention.

Please refer to FIG. 4D for another preferred embodiment of this invention with a new and improved device structure. The SiC device has a similar structure to FIG. 4C, except that the present invention in FIG. 4D further comprises a current spreading layer (CSL, as illustrated) 404′″ of the first conductivity type below the MSBPS regions with a doping concentration higher than a doping concentration of the N type epitaxial layer 402′″.

Please refer to FIG. 4E for another preferred embodiment of this invention with a new and improved device structure. The SiC device has a similar structure to FIG. 4B, except that the current spreading layer (CSL, as illustrated) 404′ in FIG. 4B doesn't exist in the present invention, and the SiC device in FIG. 4E further comprises P column (PC, as illustrated) regions 416″″ of the second conductivity type formed adjoining bottom surfaces the BPS2L 438″″ and the BPS2R 448″″ above the N+ substrate 401″″. A super junction (SJ, as illustrated) structure is thus generated by the N type epitaxial layer 402″″ and the PC region 416″″.

Please refer to FIG. 4F for another preferred embodiment of this invention with a new and improved device structure. The SiC device has a similar structure to FIG. 4E, except that the present invention further comprises an additional N buffer layer (Nb, as illustrated) 1422 with a resistivity Rb sandwiched between the N+ substrate 1401 and the PC region 1416, wherein Rb is higher than a resistivity R of the N type epitaxial layer 1402.

Please refer to FIG. 4G for another preferred embodiment of this invention with a new and improved device structure. The SiC device has a similar structure to FIG. 4E, except for the different substrate. In this invention, the SiC device is formed on a P+substrate 1401′, and further comprises an N buffer layer (Nb, as illustrated) 1422′ with a resistivity Rb sandwiched between the P+substrate 1401′ and the PC region 1416′, wherein Rb is lower than a resistivity R of the N type epitaxial layer 1402′.

Please refer to FIG. 4H for another preferred embodiment of this invention with a new and improved device structure. The SiC device has a similar structure to FIG. 4G, except that, the SiC device in FIG. 4H further comprises a plurality of heavily doped N+ regions 1440″ in the P+ substrate 1401″ to form a plurality of alternating P+ and N+ regions in the substrate.

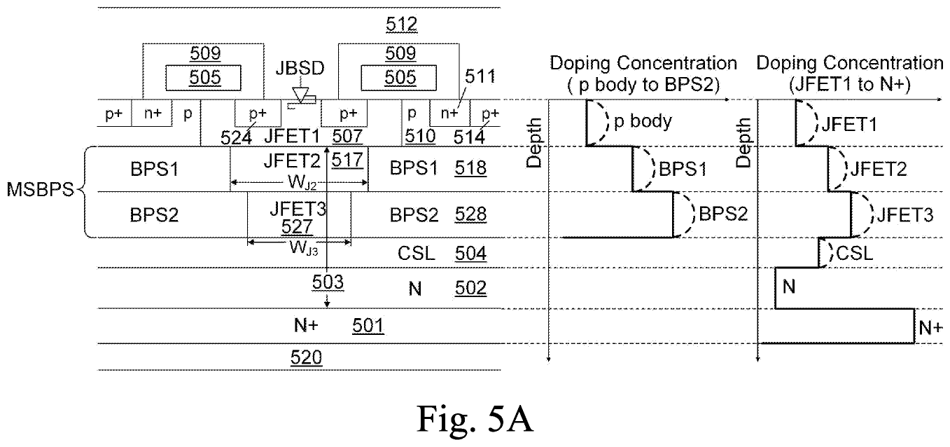

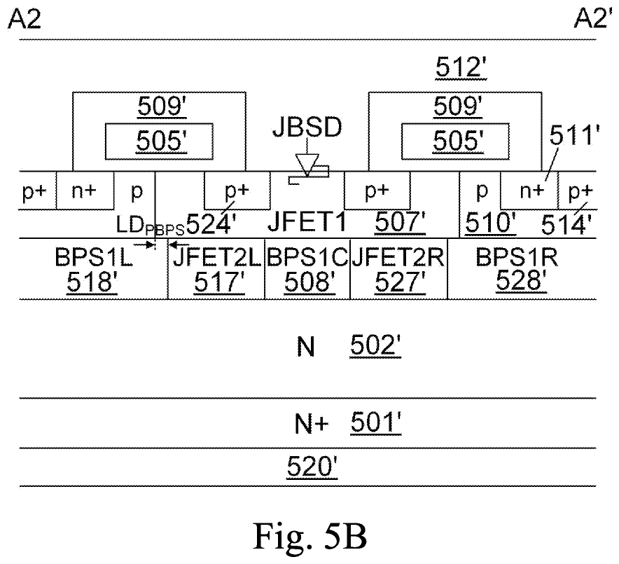

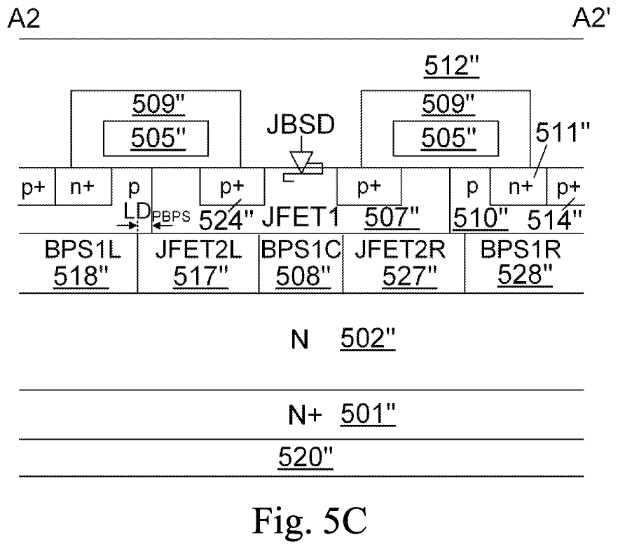

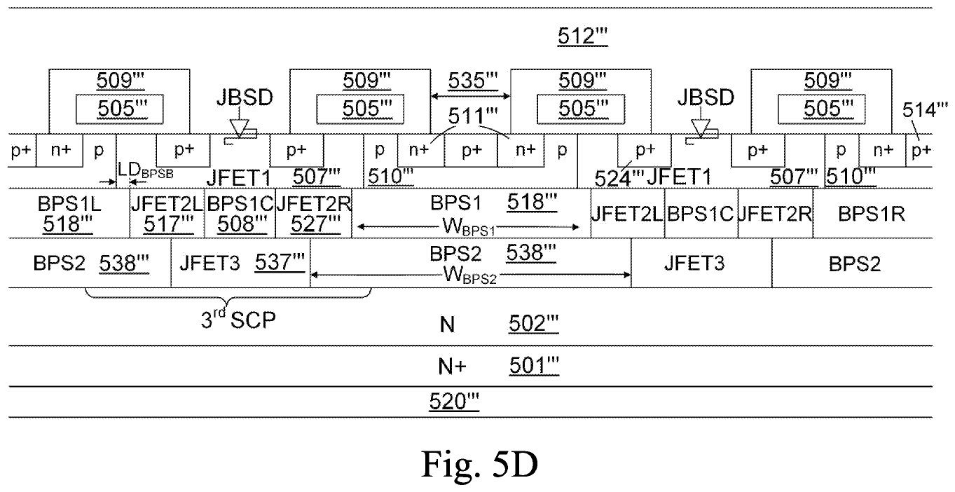

Please refer to FIG. 5A for another preferred embodiment of this invention with a new and improved device structure wherein doping concentration variations of the P type regions (from p body region to BPS2 region) and the N type regions (from JFET1 region to N+ substrate) are depicted separately along the vertical direction. The SiC device has a similar structure to FIG. 2B, except that the planar electrode in the present invention is a split gate electrode having two gate electrodes 505 padded by a gate oxide 509, and two p+ heavily doped regions 524 of a second conductivity are formed within the JFET1 region 507, wherein the two p+ regions 524 are spaced apart from the p body region 510. The SiC device further comprises a Junction barrier Schottky diode (JBSD, as illustrated) embedded between the two adjacent gate electrodes 505 by making a Schottky contact with the JFET1 region 507 between the two p+ regions 524 within the JFET1 region 507. Therefore, a Junction Barrier Schottky diode (JBSD, as illustrated) is integrated with the SiC MOSFET in a location between the two adjacent split gate electrodes 505 for the reverse conduction switching loss reduction.

Please refer to FIG. 5B for a cross-sectional view showing another preferred A2-A2′ cross section of FIG. 3A according to the present invention. The SiC device has a similar structure to FIG. 3B, except that the planar electrode in the present invention is a split gate electrode having two gate electrodes 505′ padded by a gate oxide 509′, and two p+ heavily doped regions 524′ of a second conductivity type are formed within the JFET1 region 507′, wherein the two p+ regions 524′ are spaced apart from the p body region 510′. Moreover, the SiC device further comprises a Junction barrier Schottky diode (JBSD, as illustrated) embedded between the two adjacent gate electrodes 505″ by making a Schottky contact with the JFET1 region 507′ between the two p+regions 524′ within the JFET1 region 507′. Therefore, a Junction Barrier Schottky diode (JBSD, as illustrated) is integrated with the SiC MOSFET in a location between the two adjacent split gate electrodes 505′ for the reverse conduction switching loss reduction.

Please refer to FIG. 5C for a cross-sectional view showing another preferred A2-A2′ cross section of FIG. 3A according to the present invention. The SiC device has a similar structure to FIG. 5B, except that in the present invention, the LD_{PBPS}<0.

Please refer to FIG. 5D for another preferred embodiment of this invention with a new and improved device structure. The SiC device has a similar structure to FIG. 4A, except that the planar electrode in the present invention is a split gate electrode having two gate electrodes 505′″ padded by a gate oxide 509′″, and two p+ heavily doped regions 524′″ are formed within the JFET1 region 507′″, wherein the two p+ regions 524′″ are spaced apart from the p body region 510′″. Moreover, the SiC device further comprises a Junction barrier Schottky diode (JBSD, as illustrated) embedded between the two adjacent gate electrodes 505′″ by making a Schottky contact with the JFET1 region 507′″ between the two p+ regions 524′″ within the JFET1 region 507′″. Therefore, a Junction Barrier Schottky diode (JBSD, as illustrated) is integrated with the SiC MOSFET in a location between the two adjacent split-gate electrodes 505′″ for the reverse conduction switching loss reduction.

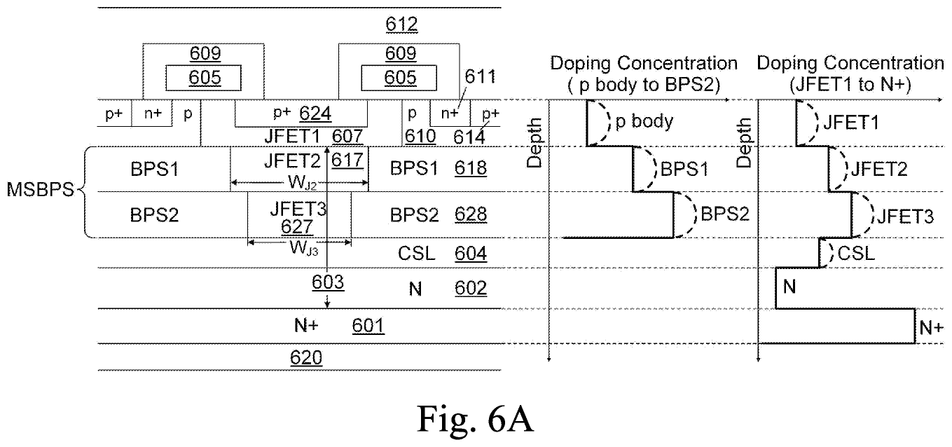

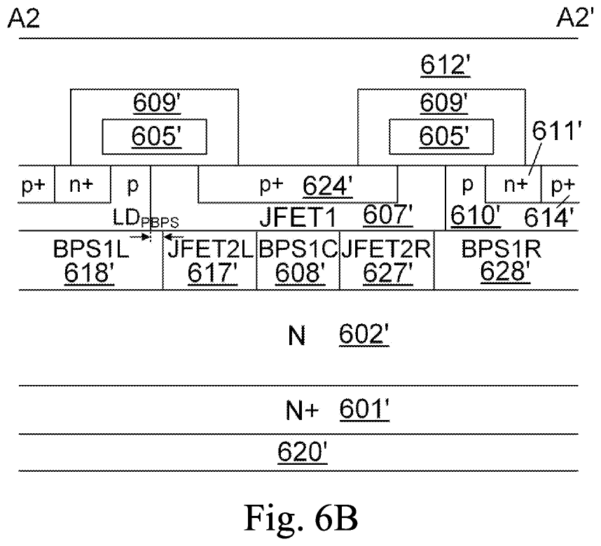

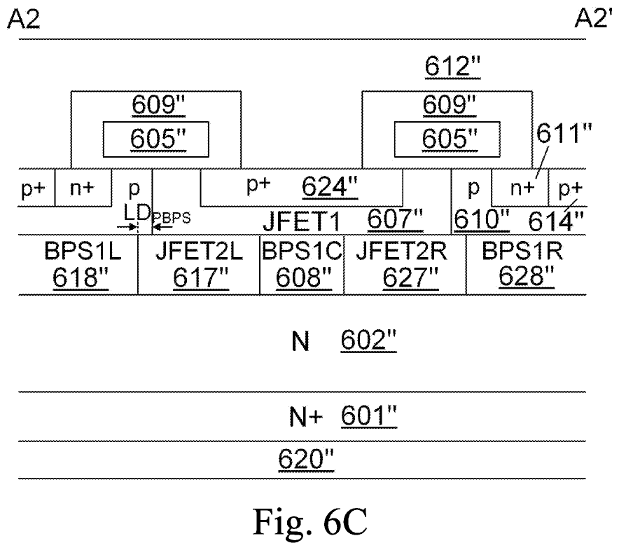

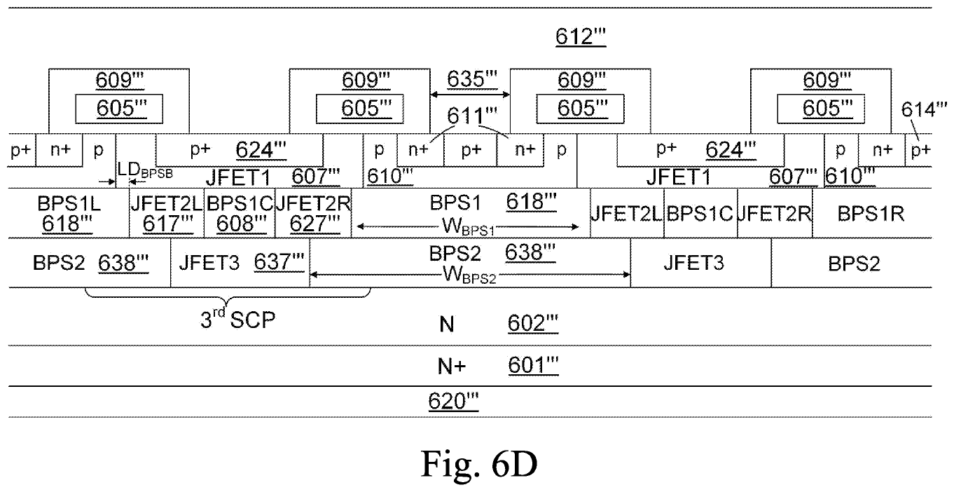

Please refer to FIG. 6A for another preferred embodiment of this invention with a new and improved device structure wherein doping concentration variations of the P type regions (from p body region to BPS2 region) and the N type regions (from JFET1 region to N+ substrate) are depicted separately along the vertical direction. The SiC device has a similar structure to FIG. 5A, except that the two p+ heavily doped regions 524 in FIG. 5A are replaced by a p+ heavily doped regions 624 within the JFET1 region 607 in the present invention, wherein the p+ region 624 is spaced apart from the p body region 610. The SiC device further comprises a P/N (P-type/N-type) junction diode embedded between the two split gate electrodes 605 by making a p+ region 624 of a second conductivity type spaced apart from the p body region 610′ within the JFET1 region 607 of the first conductivity type for gate oxide electric field reduction.

Please refer to FIG. 6B for a cross-sectional view showing another preferred A2-A2′ cross section of FIG. 3A according to the present invention. The SiC device has a similar structure to FIG. 5B, except that the two p+ heavily doped regions 524′ in FIG. 5A are replaced by a p+ heavily doped regions 624′ within the JFET1 region 607′ in the present invention, wherein the p+region 624′ is spaced apart from the body region 610′. The SiC device further comprises a P/N (P-type/N-type) junction diode embedded between the two split gate electrodes 605′ by making a p+ region 624′ of a second conductivity type spaced apart from the p body region 610′ within the JFET1 region 607′ of the first conductivity type.

Please refer to FIG. 6C for a cross-sectional view showing another preferred A2-A2′ cross section of FIG. 3A according to the present invention. The SiC device has a similar structure to FIG. 6B, except that in the present invention, the LD_{PBPS}<0.

Please refer to FIG. 6D for another preferred embodiment of this invention with a new and improved device structure. The SiC device has a similar structure to FIG. 5D, except that the two p+ heavily doped regions 524′″ in FIG. 5A are replaced by a p+ heavily doped regions 624′″ within the JFET1 region 607′″ in the present invention, wherein the p+ region 624′″ is spaced apart from the body region 610′″. The SiC device further comprises a P/N (P-type/N-type) junction diode embedded between the two split gate electrodes 605′″ by making a p+ region 624′″ of a second conductivity type spaced apart from the p body region 610′″ within the JFET1 region 607′″ of the first conductivity type.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A silicon carbide (SiC) device comprising a plurality of unit cells with each unit cell in an active area, comprising:
an epitaxial layer grown on a substrate;
a source region of a first conductivity type formed at a top portion of said epitaxial layer and encompassed in a body region of a second conductivity type;
a planar gate electrode made of a doped poly-silicon layer padded by a gate oxide;
a first type Junction Field Effect Transistor (JFET1) region of said first conductivity type formed between two adjacent said body regions;
multiple stepped buried P-shield (MSBPS) regions of said second conductivity type adjoining said body region with different doping concentrations increasing stepwise in a direction from said body region toward said substrate;
multiple stepped JFET (MSJ) regions of said first conductivity type sandwiched between two adjacent said MSBPS regions with different widths decreasing stepwise in a direction from said JFET1 region toward said substrate;
said MSJ regions with different doping concentrations increasing stepwise in a direction from said JFET1 region toward to substrate; and
an N-drift (ND) region of said first conductivity type formed between said substrate and said first type JFET1 region.

2. The SiC device of claim 1, further comprising a current spreading layer (CSL) of said first conductivity type below said MSBPS and said MSJ regions with a doping concentration higher than that of said ND region.

3. The SiC device of claim 1, wherein said planar gate electrode is a single gate electrode padded with said gate oxide having a thick oxide in its central portion.

4. The SiC device of claim 1, wherein said planar gate electrode is a split gate electrode having two gate electrodes in said each unit cell, and further comprising a Junction barrier Schottky diode (JBSD) embedded between two adjacent said gate electrodes by making a Schottky contact with said first type JFET (JFET1) region between two p+ regions of said second conductivity type within said JFET1 region, wherein said two p+ regions are spaced apart from said body region.

5. The SiC device of claim 1, wherein said planar gate electrode is a split gate electrode having two gate electrodes in said each unit cell, and further comprising a P/N (P-type/N-type) junction diode embedded between two adjacent said gate electrodes by making a p+ region of said second conductivity type within said JFET1 region, wherein said p+ region is spaced apart from said body region.

6. The SiC device of claim 1, wherein said MSBPS regions comprise at least two buried P-shield (BPS) regions including a top first BPS (BPS1) region with a doping concentration D_{BPS1} and a bottom second BPS (BPS2) region with a doping concentration D_{BPS2}, wherein said D_{BPS1}<D_{BPS2}; said MSJ regions comprise at least two JFET regions including a second type JFET (JFET2) region with a width W_{J2} and a doping concentration D_{JFET2} and a third type JFET (JFET3) region below said JFET2 region with a width W_{J3} and a doping concentration D_{JFET3}, wherein said W_{J2}>W_{J3} and said D_{JFET2}<D_{JFET3}, while W_{J2} is less than a width W_{J1} of said JFET1 region and D_{JFET2} is higher than a doping concentration D_{JFET1} of said JFET1 region, the relationships among widths and doping concentrations of said three type JFET regions are said W_{J1}>W_{J2}>W_{J3} and said D_{JFET1}<D_{JFET2}<D_{JFET3}; and said MSBPS and said MSJ regions have an uniform doping concentration profile or a non-uniform doping profile with a peak doping concentration in each region.

7. The SiC device of claim 1, further comprising a super junction structure comprising a P column region of said second conductivity type disposed above said substrate.

8. The SiC device of claim 7, wherein said substrate has said first conductivity type and further comprises a buffer layer of said first conductivity type with a resistivity Rb sandwiched between said substrate and said epitaxial layer with a resistivity R, wherein said R<Rb.

9. The SiC device of claim 7, wherein said substrate has said second conductivity type and further comprises a buffer layer of said first conductivity type with a resistivity Rb sandwiched between said substrate and said epitaxial layer with a resistivity R, wherein said R>Rb.

10. The SiC device of claim 7, wherein said substrate has said second conductivity type, further comprises a buffer layer of said first conductivity type formed sandwiched between said substrate and said epitaxial layer; a plurality of heavily doped regions of said first conductivity type in said substrate to form a plurality of alternating P+ and N+ regions in said substrate.

11. A SiC device comprising a plurality of unit cells with each unit cell in an active area, comprising:
an epitaxial layer grown on a substrate;
a source region of a first conductivity type formed at a top portion of said epitaxial layer and encompassed in a body region of a second conductivity type;
a planar gate electrode made of a doped poly-silicon layer padded by a gate oxide;
a first type JFET (JFET1) region of said first conductivity type formed between two adjacent said body regions;
a first BPS (BPS1) region of said second conductivity type formed below said body region and said JFET1 region having a left side portion BPS1L, a center portion BPS1C, a right side portion BPS1R and connection portions BPS1G;
said BPS1G connecting said BPS1C together with BPS1L and/or BPS1R to a source metal through said body region;
a second type JFET (JFET2) region having a left side portion JFET2L formed between said BPS1L and BPS1C, and a right side portion JFET2R formed between said BPS1C and said BPS1R;
said JFET2 region has a doping concentration higher than that of said JFET1 region; and
an ND region of said first conductivity type is formed between said substrate and said JFET1 region.

12. The SiC device of claim 11, wherein said planar gate electrode is a single gate electrode padded with said gate oxide having a thick oxide in its central portion.

13. The SiC device of claim 11, wherein said planar gate electrode is a split gate electrode having two gate electrodes in said each unit cell, and further comprising a JBSD embedded between two adjacent said gate electrodes by making a Schottky contact with said JFET1 region between two p+ regions of said second conductivity type within said JFET1 region. wherein said two p+ regions are spaced apart from said body region

14. The SiC device of claim 11, wherein said planar gate electrode is a split gate electrode having two gate electrodes in said each unit cell, and further comprising a P/N (P-type/N-type) junction diode embedded between two adjacent said gate electrodes by making a p+ region of said second conductivity type within said JFET1 region, wherein said p+ region is spaced apart from said body region.

15. The SiC device of claim 11, further comprising a second BPS (BPS2) region of said second conductivity type formed below said BPS1 region and a third type JFET (JFET3) region formed between two adjacent said BPS2 regions; said BPS2 region having a doping concentration higher than that of said BPS1 region, and having a width greater than that of said BPS1 region.

16. The SiC device of claim 11, further comprising a CSL below said BPS2 and said JFET3 regions with a doping concentration higher than that of said ND region.

17. The SiC device of claim 11, further comprising a super junction structure comprising a P column region of said second conductivity type disposed above said substrate.

18. The SiC device of claim 17, wherein said substrate has said first conductivity type and further comprises a buffer layer of said first conductivity type with a resistivity Rb sandwiched between said substrate and said epitaxial layer with a resistivity R, wherein said R<Rb.

19. The SiC device of claim 17, wherein said substrate has said second conductivity type and further comprises a buffer layer of said first conductivity type with a resistivity Rb sandwiched between said substrate and said epitaxial layer with a resistivity R, wherein said R>Rb.

20. The SiC device of claim 17, wherein said substrate has said second conductivity type, further comprises a buffer layer of said first conductivity type formed sandwiched between said substrate and said epitaxial layer; a plurality of heavily doped regions of said first conductivity type in said substrate to form a plurality of alternating P+ and N+ regions in said substrate.
